(19) United States
(12) Patent Application Publication
(10) Pub. No.: US 2026/0005654 A1
(43) Pub. Date: Jan. 1, 2026

(54) METHODS AND DEVICES INCLUDING AMPLIFIER CIRCUITRY

(71) Applicant: Intel Corporation, Santa Clara, CA (US)

(72) Inventors: Abhishek AGRAWAL, Portland, OR (US); Steven CALLENDER, Denver, CO (US)

(21) Appl. No.: 18/757,597

(22) Filed: Jun. 28, 2024

(51) Int. Cl. H03F 1/56; H03F 3/45

(52) U.S. Cl. CPC H03F 1/565; H03F 3/45183; H03F 3/45493; H03F 2200/294; H03F 2200/451

(57) ABSTRACT

An amplifier circuitry, may include a plurality of differential pair amplifiers connected to differential input connections and differential output connections, and a common mode return current connection connected to the each differential pair amplifier of the plurality of differential pair amplifiers, wherein the common mode return current connection includes an insulation layer between a first portion of the common mode return current connection and a second portion of the common mode return current connection for common-mode stability.

### TECHNICAL FIELD

Various aspects of this disclosure relate to an amplifier circuitry for radio communication.

### BACKGROUND

The complexity of communication systems continues to increase in order to meet the requirements of the market and the users in terms of many aspects, including speed, reliability, energy efficiency, coverage, and scalability. Recent communication systems may require many inter-related components, blocks, or functions working together in order to perform improvements to such aspects in communication elements such as receivers, transmitters, or alternatively transceivers for devices that may transmit and receive communication signals. One of the exemplary reasons for the recent challenges in communication systems may be considered as the recent implementation of radio communication using signals having frequencies over one gigahertz. The communication may generally take the form of radio communication at such frequencies, however other forms of transmission mediums may also be used, such as wired communication, satellite communication, or optical communication.

To support increases in data traffic, transceivers need to support wider bandwidths (BW) and higher-order modulations schemes. Furthermore, it is also desired that the transceivers would spend energy efficiently and have reduced complexity. Further, considering the employment of millimeter waves (mmWave) and sub-terahertz (sub-THz) frequencies associated with portions of the electromagnetic spectrum characterized by wavelengths ranging from approximately 1 millimeter down to submillimeter sizes, there may be room for development of amplifier circuitries with improved power and stability.

### BRIEF DESCRIPTION OF FIGURES

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIGS. 1 and 2 depict a general network and device architecture for wireless communications;

FIG. 3 shows an exemplary illustration of various communication elements of an apparatus for a wireless communication device;

FIG. 4 shows schematically a block diagram of an example radio frequency (RF) front end circuit;

FIG. 5 shows schematically an example of a RF transceiver circuitry;

FIG. 6 shows schematically an example of an amplifier circuitry in accordance with various aspects provided herein;

FIG. 7 shows schematically an exemplary illustration of an amplifier circuitry;

FIG. 8 shows an example illustration of a T model of a transformer;

FIGS. 9A-9C show respective schematic examples of an amplifier circuitry in accordance with aspects described herein.

### DESCRIPTION

Power amplifiers (PAs) may be used in RF circuits to provide amplification to communication signals. High data rate (10+ Gb/s) communication may be enabled by the large available spectrum at mmWave/sub-THz (e.g. 30-300 GHz) frequencies. Radio communication devices operating at these frequencies may use medium-to-high power (Psat >+5 dBm) power amplifiers (PA) in a single radio frequency (RF) chain or in multiple RF-chains (e.g. within phased arrays) to compensate path loss thereby restoring healthy link budget. In view of various constraints associated with such operational frequencies, medium-to-high power PAs at mmWave/subTHz frequency may be challenging due to increased passive loss and limited device gain.

For example, at such higher frequencies like mmWave and sub-THz, passive components of RF-chains, such as transmission lines, filters, and matching networks may exhibit higher insertion loss which may result in a considerable effect for the overall power efficiency of the amplifier. Further, amplifier circuitries configured for such operational frequencies may require active devices like gallium nitride (GaN) or gallium arsenide (GaAs) transistors. However, these devices might have limited gain at such operational frequencies, which may result in employing multiple stages of amplification or complex circuitries to achieve desired power levels.

Furthermore, during employment of higher power levels, thermal dissipation may become a concern for stability. Heat management becomes crucial to maintain the reliability and performance of the amplifier, especially considering the compact sizes often required in modern electronics. Moreover, nonlinear behavior in active devices may become more prominent at these frequencies, which may affect the linearity and distortion characteristics of the amplifier circuitry.

Especially, magnetic coupling effects at mmWave/sub-THz frequencies may significantly impact the performance of systems and components operating within these ranges. Illustratively, traces and conductors on a printed circuit board (PCB) or within an integrated circuit can exhibit increased inductive behavior at higher frequencies due to their physical dimensions becoming comparable to the wavelength of the signals. This may lead to unintended coupling between different parts of a circuit, such as different portions of an amplifier circuitry. Magnetic fields generated by high-frequency signals can induce currents in nearby conductive elements, which may lead to unintentional radiation and crosstalk between adjacent traces, components, or circuits. This can degrade the signal quality and overall performance of the system through the propagation of magnetic feedback currents.

It is further to be considered that certain materials, including conductors and dielectrics, might exhibit increased magnetic losses at these frequencies. Such magnetic losses can lead to reduced efficiency in components and devices, in particular of amplifier circuitry, impacting their performance as they interact with magnetic fields. Magnetic effects may further influence the resonance behavior of circuits and antennas, affecting impedance matching and tuning at specific frequencies. Achieving the desired impedance matching may become critical for maximizing power transfer and signal integrity amidst magnetic feedback currents.

In accordance with various aspects of this disclosure, an amplifier circuitry may include substantially identical-structured multiple amplifier circuits. Substantially identical structures may include substantially same physical layout of amplifier circuits (e.g. components within the amplifier circuits are arranged in the same (or substantially the same) manner, following a similar layout and placement), and/or substantially same electrical characteristics (e.g. components such as transistors, resistors, or capacitors of the amplifier circuits have identical or substantially identical specifications or values to cause each circuit to perform similarly), and/or substantially same functional design (i.e. the amplifier circuits operate in the same way (or substantially the same way) by utilizing similar configurations and principles to achieve comparable functionality and performance.

Through obtained high degree of similarity in how the amplifier circuits are built as described above, arranged, and operate within the amplifier circuitry, generally a uniform performance, a balanced load sharing, and/or a reduction of manufacturing complexity may be obtained. In some examples, the aspects described herein may be particularly beneficial for amplifier circuitries with repeating structures. Exemplarily, an amplifier circuitry may be or may include a Neutralized Differential Pair (NDP) array including multiple NDPs, which may be implemented within an integrated circuits or on a printed circuit board (PCB). In an amplifier circuit, a differential pair configuration may include two active devices (usually transistors) that may be configured to amplify the difference between two input signals while rejecting common-mode signals. Such a configuration may be commonly used because of its balanced characteristics and its ability to reduce noise and certain distortions. However, in high-frequency circuits, parasitic capacitances and inductances may result in unwanted oscillations or instability of the amplifier circuit, particularly at higher frequencies.

An NDP may be used to counteract such unwanted effects. An NDP may include one or more neutralization components (which may include circuits) to intentionally introduce feedback to cancel out the parasitic effects through neutralization of the reactance in the differential pair. By neutralizing the differential pair, the aim may be to maintain the desired amplification of the differential signal while suppressing or eliminating potential instabilities or oscillations caused by parasitic elements, especially in high-frequency applications where such effects can be more pronounced. It is particularly important to achieve stable and reliable performance in RF and high-frequency amplifier designs.

An NDP array may include multiple NDPs to collectively provide higher amplification levels by combining the differential signals from multiple pairs. When NDPs are provided in an array, differential pairs can work together to maintain stability, reduce unwanted oscillations, and improve the overall performance of the system, especially in high-frequency applications where instability may be a concern. Furthermore, an NDP array may be scaled up or down to meet different desired requirements, allowing for flexibility in design and application.

At mmWave or sub-THz frequencies, the physical dimensions of an NDP array may quickly become comparable to the operational wavelength of the signals, which may increase the impact of distributed effects of the interconnect over device, resulting in parasitic inductance and increased magnetic feedback between the input and output connections. These effects may degrade both gain and stability, and place a practical limit on the NDP array size for a given operating frequency thereby limiting the attainable output power.

Traditionally, array size of an NDP array may be limited to reduce such effects, resulting in a lower gain and output power. Additionally, or alternatively, an NDP may include additional interconnects through multiple parallel NDP arrays, which may introduce further complexity for design and implementation. For example, an NDP array may be implemented via traditional power combining methods via designated controlled impedance interfaces for isolation.

However, these approaches may have certain fallbacks. Correspondingly, NDP array size may be limited to ensure that the inductive effects and associated gain/stability degradation are negligible. This limitation may be challenging to maintain the stability of the power amplifier (PA) circuitry, especially at mmWave/sub-THz frequencies where passive component losses and nonlinear behavior of active devices may become significant. For example, in the case of a PA in a transmitter, this limitation may restrict the communication distance. In another example for phased-arrays, a larger number of antennas may be required to achieve the desired total radiated power.

In some examples, to achieve larger output power, multiple rows of the limited size NDP array may be placed in parallel with additional interconnects on the input and output to connect the rows as a single device. This approach may allow for an increase in output power while limiting the maximum array size for any single array. However, this may also introduce challenges related to common mode stability due to increased feedback, both electric and magnetic, at which circuit designers must exercise additional caution to ensure the stability of the fully connected amplifier, as these interconnects can raise stability issues due to increased feedback, both electric and magnetic. Traditionally used common mode stabilization techniques, such as the addition of a series resistor at the center tap of the input transformer and common mode inductor degeneration, may be effective for capacitive feedback but become less effective in the presence of undesired magnetic coupling.

In some cases, another method for increasing output power is traditional power combining may include combining the output power across multiple amplifier channels using properly designed controlled impedance interfaces to ensure isolation across each amplifier channel. An example of this approach may include employment of the Wilkinson power combiner, which may provide isolation and minimize interaction between amplifier channels. However, with use of such methods, transmission lines may occupy a larger area than more compact methods, resulting in a direct area penalty. This area penalty can limit the number of transceivers that can be co-integrated on silicon, which can be disadvantageous for phased-array systems. Even in this method, common mode stability may be an issue.

In accordance with various aspects described herein, the challenges of achieving the desired output power while ensuring stability in power amplifier circuitry operating at mmWave/sub-THz frequencies are addressed. By carefully designing the array size and employing power combining techniques, it is possible to mitigate the effects of inductive losses, nonlinear behavior, and magnetic coupling, thereby enhancing the performance and reliability of the amplifier circuitry, in particular with respect to common mode stability of the amplifier circuitry.

Common mode stability may refer to the ability of the amplifier circuitry to maintain consistent performance and behavior in the presence of common mode disturbances or interference. In this context, common mode stability may particularly be challenging due to the distributed effects at mm Wave/sub-THz frequencies. In particular, with respect to the presence of differential input and output signals, the neutralization of device capacitance (C_{gd}) using capacitors may be effective, however this approach may also increase feedback for common mode signals, which may degrade the common-mode stability margin. As the NDP array size increases, the common mode distributed inductance on the input and output connections of differential amplifier pairs of the amplifier circuitry and their associated coupling may create a mechanism for magnetic feedback. This feedback may cause instability, which may result in the need to limit the array size or employ robust power combining techniques, such as Wilkinson power combiners, to ensure stability.

Illustratively, for a PA design at sub-THz frequencies (100+ GHZ) which may require sufficiently high output power with robust stability, less process, voltage and temperature (PVT) sensitivity and wider bandwidth. Through implementation of various aspects described herein, larger NDP arrays at mmWave/sub-THz frequencies may be provided in order to realize these higher power PAs. For mm-Wave PA (e.g. 20-70 GHZ), although the magnetic feedback may be considered to be less severe for a given array size due to the lower frequency of operation in comparison with sub-THZ operation, typically at these frequencies, higher output power may be desirable which may require increasing the array size of the amplifier circuitry. In accordance with various aspects described herein, array size of the amplifier circuitry may be increased while still yielding improved stability.

The apparatuses and methods of this disclosure may utilize or be related to radio communication technologies. While some examples may refer to specific radio communication technologies, the examples provided herein may be similarly applied to various other radio communication technologies, both existing and not yet formulated, particularly in cases where such radio communication technologies share similar features as disclosed regarding the following examples. Various exemplary radio communication technologies that the apparatuses and methods described herein may utilize include, but are not limited to: a Global System for Mobile Communications (“GSM”) radio communication technology, a General Packet Radio Service (“GPRS”) radio communication technology, an Enhanced Data Rates for GSM Evolution (“EDGE”) radio communication technology, and/or a Third Generation Partnership Project (“3GPP”) radio communication technology, for example Universal Mobile Telecommunications System (“UMTS”), Freedom of Multimedia Access (“FOMA”), 3GPP Long Term Evolution (“LTE”), 3GPP Long Term Evolution Advanced (“LTE Advanced”), Code division multiple access 2000 (“CDMA2000”), Cellular Digital Packet Data (“CDPD”), Mobitex, Third Generation (3G), Circuit Switched Data (“CSD”), High-Speed Circuit-Switched Data (“HSCSD”), Universal Mobile Telecommunications System (“Third Generation”) (“UMTS (3G)”), Wideband Code Division Multiple Access (Universal Mobile Telecommunications System) (“W-CDMA (UMTS)”), High Speed Packet Access (“HSPA”), High-Speed Downlink Packet Access (“HSDPA”), High-Speed Uplink Packet Access (“HSUPA”), High Speed Packet Access Plus (“HSPA+”), Universal Mobile Telecommunications System-Time-Division Duplex (“UMTS-TDD”), Time Division-Code Division Multiple Access (“TD-CDMA”), Time Division-Synchronous Code Division Multiple Access (“TD-CDMA”), 3rd Generation Partnership Project Release 8 (Pre-4th Generation) (“3GPP Rel. 8 (Pre-4G)”), 3GPP Rel. 9 (3rd Generation Partnership Project Release 9), 3GPP Rel. 10 (3rd Generation Partnership Project Release 10), 3GPP Rel. 11 (3rd Generation Partnership Project Release 11), 3GPP Rel. 12 (3rd Generation Partnership Project Release 12), 3GPP Rel. 13 (3rd Generation Partnership Project Release 13), 3GPP Rel. 14 (3rd Generation Partnership Project Release 14), 3GPP Rel. 15 (3rd Generation Partnership Project Release 15), 3GPP Rel. 16 (3rd Generation Partnership Project Release 16), 3GPP Rel. 17 (3rd Generation Partnership Project Release 17), 3GPP Rel. 18 (3rd Generation Partnership Project Release 18), 3GPP 5G, 3GPP LTE Extra, LTE-Advanced Pro, LTE Licensed-Assisted Access (“LAA”), MuLTEfire, UMTS Terrestrial Radio Access (“UTRA”), Evolved UMTS Terrestrial Radio Access (“E-UTRA”), Long Term Evolution Advanced (4th Generation) (“LTE Advanced (4G)”), cdmaOne (“2G”), Code division multiple access 2000 (Third generation) (“CDMA2000 (3G)”), Evolution-Data Optimized or Evolution-Data Only (“EV-DO”), Advanced Mobile Phone System (1st Generation) (“AMPS (1G)”), Total Access Communication arrangement/Extended Total Access Communication arrangement (“TACS/ETACS”), Digital AMPS (2nd Generation) (“D-AMPS (2G)”), Push-to-talk (“PTT”), Mobile Telephone System (“MTS”), Improved Mobile Telephone System (“IMTS”), Advanced Mobile Telephone System (“AMTS”), OLT (Norwegian for Offentlig Landmobil Telefoni, Public Land Mobile Telephony), MTD (Swedish abbreviation for Mobiltelefonisystem D, or Mobile telephony system D), Public Automated Land Mobile (“Autotel/PALM”), ARP (Finnish for Autoradiopuhelin, “car radio phone”), NMT (Nordic Mobile Telephony), High capacity version of NTT (Nippon Telegraph and Telephone) (“Hicap”), Cellular Digital Packet Data (“CDPD”), Mobitex, DataTAC, Integrated Digital Enhanced Network (“iDEN”), Personal Digital Cellular (“PDC”), Circuit Switched Data (“CSD”), Personal Handy-phone System (“PHS”), Wideband Integrated Digital Enhanced Network (“WiDEN”), iBurst, Unlicensed Mobile Access (“UMA”), also referred to as also referred to as 3GPP Generic Access Network, or GAN standard), Zigbee, Bluetooth®, Wireless Gigabit Alliance (“WiGig”) standard, mmWave standards in general (wireless systems operating at 10-300 GHz and above such as WiGig, IEEE 802.11ad, IEEE 802.11ay, etc.), technologies operating above 300 GHz and THz bands, (3GPP/LTE based or IEEE 802.11p and other) Vehicle-to-Vehicle (“V2V”) and Vehicle-to-X (“V2X”) and Vehicle-to-Infrastructure (“V2I”) and Infrastructure-to-Vehicle (“12V”) communication technologies, 3GPP cellular V2X, DSRC (Dedicated Short Range Communications) communication arrangements such as Intelligent-Transport-Systems, and other existing, developing, or future radio communication technologies.

The apparatuses and methods described herein may use such radio communication technologies according to various spectrum management schemes, including, but not limited to, dedicated licensed spectrum, unlicensed spectrum, (licensed) shared spectrum (such as LSA=Licensed Shared Access in 2.3-2.4 GHz, 3.4-3.6 GHZ, 3.6-3.8 GHz and further frequencies and SAS=Spectrum Access System in 3.55-3.7 GHZ and further frequencies), and may use various spectrum bands including, but not limited to, IMT (International Mobile Telecommunications) spectrum (including 450-470 MHz, 790-960 MHz, 1710-2025 MHz, 2110-2200 MHZ, 2300-2400 MHZ, 2500-2690 MHz, 698-790 MHz, 610-790 MHZ, 3400-3600 MHZ, etc., where some bands may be limited to specific region(s) and/or countries), IMT-advanced spectrum, IMT-2020 spectrum (expected to include 3600-3800 MHZ, 3.5 GHz bands, 700 MHz bands, bands within the 24.25-86 GHz range, etc.), spectrum made available under FCC's “Spectrum Frontier” 5G initiative (including 27.5-28.35 GHZ, 29.1-29.25 GHz, 31-31.3 GHZ, 37-38.6 GHz, 38.6-40 GHz, 42-42.5 GHZ, 57-64 GHZ, 64-71 GHZ, 71-76 GHZ, 81-86 GHz and 92-94 GHz, etc.), the ITS (Intelligent Transport Systems) band of 5.9 GHZ (typically 5.85-5.925 GHZ) and 63-64 GHz, bands currently allocated to WiGig such as WiGig Band 1 (57.24-59.40 GHZ), WiGig Band 2 (59.40-61.56 GHZ) and WiGig Band 3 (61.56-63.72 GHZ) and WiGig Band 4 (63.72-65.88 GHZ), the 70.2 GHZ-71 GHz band, any band between 65.88 GHz and 71 GHZ, bands currently allocated to automotive radar applications such as 76-81 GHZ, and future bands including 94-300 GHz and above. Furthermore, the apparatuses and methods described herein can also employ radio communication technologies on a secondary basis on bands such as the TV White Space bands (typically below 790 MHZ) where e.g. the 400 MHz and 700 MHz bands are prospective candidates. Besides cellular applications, specific applications for vertical markets may be addressed such as PMSE (Program Making and Special Events), medical, health, surgery, automotive, low-latency, drones, etc. applications. Furthermore, the apparatuses and methods described herein may also use radio communication technologies with a hierarchical application, such as by introducing a hierarchical prioritization of usage for different types of users (e.g., low/medium/high priority, etc.), based on a prioritized access to the spectrum e.g., with highest priority to tier-1 users, followed by tier-2, then tier-3, etc. users, etc. The apparatuses and methods described herein can also use radio communication technologies with different Single Carrier or OFDM flavors (CP-OFDM, SC-FDMA, SC-OFDM, filter bank-based multicarrier (FBMC), OFDMA, etc.) and e.g. 3GPP NR (New Radio), which can include allocating the OFDM carrier data bit vectors to the corresponding symbol resources.

For purposes of this disclosure, radio communication technologies may be classified as one of a Short Range radio communication technology or Cellular Wide Arca radio communication technology. Short Range radio communication technologies may include Bluetooth, WLAN (e.g., according to any IEEE 802.11 standard), and other similar radio communication technologies. Cellular Wide Area radio communication technologies may include Global System for Mobile Communications (“GSM”), Code Division Multiple Access 2000 (“CDMA2000”), Universal Mobile Telecommunications System (“UMTS”), Long Term Evolution (“LTE”), General Packet Radio Service (“GPRS”), Evolution-Data Optimized (“EV-DO”), Enhanced Data Rates for GSM Evolution (“EDGE”), High Speed Packet Access (HSPA; including High Speed Downlink Packet Access (“HSDPA”), High Speed Uplink Packet Access (“HSUPA”), HSDPA Plus (“HSDPA+”), and HSUPA Plus (“HSUPA+”)), Worldwide Interoperability for Microwave Access (“WiMax”) (e.g., according to an IEEE 802.16 radio communication standard, e.g., WiMax fixed or WiMax mobile), etc., and other similar radio communication technologies. Cellular Wide Area radio communication technologies also include “small cells” of such technologies, such as microcells, femtocells, and picocells. Cellular Wide Area radio communication technologies may be generally referred to herein as “cellular” communication technologies.

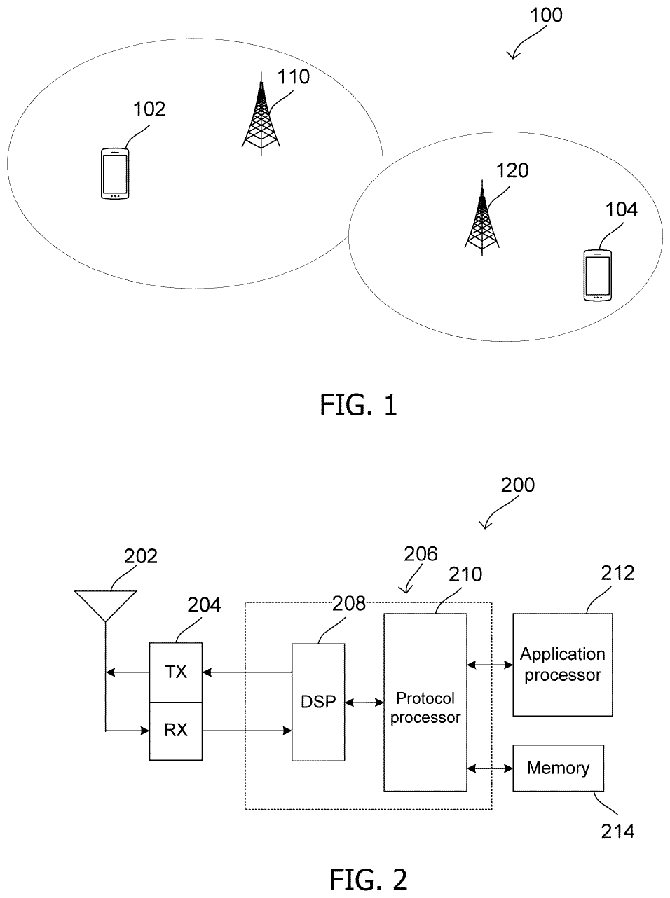

FIGS. 1 and 2 depict a general network and device architecture for wireless communications. In particular, FIG. 1 shows exemplary radio communication network 100 according to some aspects, which may include terminal devices 102 and 104 and network access nodes 110 and 120. Radio communication network 100 may communicate with terminal devices 102 and 104 via network access nodes 110 and 120 over a radio access network. Although certain examples described herein may refer to a particular radio access network context (e.g., LTE, UMTS, GSM, other 3rd Generation Partnership Project (3GPP) networks, WLAN/WiFi, Bluetooth, 5G NR, mmWave, etc.), these examples are demonstrative and may therefore be readily applied to any other type or configuration of radio access network. The number of network access nodes and terminal devices in radio communication network 100 is exemplary and is scalable to any amount.

In an exemplary cellular context, network access nodes 110 and 120 may be base stations (e.g., cNodeBs, NodeBs, Base Transceiver Stations (BTSs), gNodeBs, or any other type of base station), while terminal devices 102 and 104 may be cellular terminal devices (e.g., Mobile Stations (MSs), User Equipments (UEs), or any type of cellular terminal device). Network access nodes 110 and 120 may therefore interface (e.g., via backhaul interfaces) with a cellular core network such as an Evolved Packet Core (EPC, for LTE), Core Network (CN, for UMTS), or other cellular core networks, which may also be considered part of radio communication network 100. The cellular core network may interface with one or more external data networks. In an exemplary short-range context, network access node 110 and 120 may be access points (APs, e.g., WLAN or WiFi APs), while terminal device 102 and 104 may be short range terminal devices (e.g., stations (STAs)). Network access nodes 110 and 120 may interface (e.g., via an internal or external router) with one or more external data networks. Network access nodes 110 and 120 and terminal devices 102 and 104 may include one or multiple transmission/reception points (TRPs).

Network access nodes 110 and 120 (and, optionally, other network access nodes of radio communication network 100 not explicitly shown in FIG. 1) may accordingly provide a radio access network to terminal devices 102 and 104 (and, optionally, other terminal devices of radio communication network 100 not explicitly shown in FIG. 1). In an exemplary cellular context, the radio access network provided by network access nodes 110 and 120 may enable terminal devices 102 and 104 to wirelessly access the core network via radio communications. The core network may provide switching, routing, and transmission, for traffic data related to terminal devices 102 and 104, and may further provide access to various internal data networks (e.g., control nodes, routing nodes that transfer information between other terminal devices on radio communication network 100, etc.) and external data networks (e.g., data networks providing voice, text, multimedia (audio, video, image), and other Internet and application data). In an exemplary short-range context, the radio access network provided by network access nodes 110 and 120 may provide access to internal data networks (e.g., for transferring data between terminal devices connected to radio communication network 100) and external data networks (e.g., data networks providing voice, text, multimedia (audio, video, image), and other Internet and application data).

The radio access network and core network (if applicable, such as for a cellular context) of radio communication network 100 may be governed by communication protocols that can vary depending on the specifics of radio communication network 100. Such communication protocols may define the scheduling, formatting, and routing of both user and control data traffic through radio communication network 100, which includes the transmission and reception of such data through both the radio access and core network domains of radio communication network 100. Accordingly, terminal devices 102 and 104 and network access nodes 110 and 120 may follow the defined communication protocols to transmit and receive data over the radio access network domain of radio communication network 100, while the core network may follow the defined communication protocols to route data within and outside of the core network. Exemplary communication protocols include LTE, UMTS, GSM, WiMAX, Bluetooth, WiFi, mmWave, etc., any of which may be applicable to radio communication network 100.

FIG. 2 shows an exemplary internal configuration of a communication device according to various aspects provided in this disclosure. The communication device may include various aspects of network access nodes 110, 120 or various aspects of a terminal device 102 as well. The communication device 200 may include antenna system 202, radio frequency (RF) transceiver 204, baseband modem 206 (including digital signal processor 208 and protocol controller 210), application processor 212, and memory 214. Although not explicitly shown in FIG. 2, in some aspects communication device 200 may include one or more additional hardware and/or software components, such as processors/microprocessors, controllers/microcontrollers, other specialty or generic hardware/processors/circuits, peripheral device(s), memory, power supply, external device interface(s), subscriber identity module(s) (SIMs), user input/output devices (display(s), keypad(s), touchscreen(s), speaker(s), external button(s), camera(s), microphone(s), etc.), or other related components.

Communication device 200 may transmit and receive radio signals on one or more radio access networks. Baseband modem 206 may direct such communication functionality of communication device 200 according to the communication protocols associated with each radio access network, and may execute control over antenna system 202 and RF transceiver 204 to transmit and receive radio signals according to the formatting and scheduling parameters defined by each communication protocol. Although various practical designs may include separate communication components for each supported radio communication technology (e.g., a separate antenna, RF transceiver, digital signal processor, and controller), for purposes of conciseness the configuration of communication device 200 shown in FIG. 2 depicts only a single instance of such components.

Communication device 200 may transmit and receive wireless signals with antenna system 202. Antenna system 202 may be a single antenna or may include one or more antenna arrays that each include multiple antenna elements. For example, antenna system 202 may include an antenna array at the top of communication device 200 and a second antenna array at the bottom of communication device 200. In some aspects, antenna system 202 may additionally include analog antenna combination and/or beamforming circuitry.

In the receive (RX) path, RF transceiver 204 may receive analog radio frequency signals from antenna system 202 and perform analog and digital RF front-end processing on the analog radio frequency signals to produce digital baseband samples (e.g., In-Phase/Quadrature (IQ) samples) to provide to baseband modem 206. RF transceiver 204 may include analog and digital reception components including amplifiers (e.g., Low Noise Amplifiers (LNAs)), filters, RF demodulators (e.g., RF IQ demodulators)), and analog-to-digital converters (ADCs), which RF transceiver 204 may utilize to convert the received radio frequency signals to digital baseband samples. In the transmit (TX) path, RF transceiver 204 may receive digital baseband samples from baseband modem 206 and perform analog and digital RF front-end processing on the digital baseband samples to produce analog radio frequency signals to provide to antenna system 202 for wireless transmission. RF transceiver 204 may thus include analog and digital transmission components including amplifiers (e.g., Power Amplifiers (PAs), filters, RF modulators (e.g., RF IQ modulators), and digital-to-analog converters (DACs), which RF transceiver 204 may utilize to mix the digital baseband samples received from baseband modem 206 and produce the analog radio frequency signals for wireless transmission by antenna system 202. In some aspects baseband modem 206 may control the radio transmission and reception of RF transceiver 204, including specifying the transmit and receive radio frequencies for operation of RF transceiver 204. In some aspects, RF transceiver 204 may include one or more amplifier circuitries as described in this disclosure, for example as PAs.

As shown in FIG. 2, baseband modem 206 may include digital signal processor 208, which may perform physical layer (PHY, Layer 1) transmission and reception processing to, in the transmit path, prepare outgoing transmit data provided by protocol controller 210 for transmission via RF transceiver 204, and, in the receive path, prepare incoming received data provided by RF transceiver 204 for processing by protocol controller 210. Digital signal processor 208 may be configured to perform one or more of error detection, forward error correction encoding/decoding, channel coding and interleaving, channel modulation/demodulation, physical channel mapping, radio measurement and search, frequency and time synchronization, antenna diversity processing, power control and weighting, rate matching/de-matching, retransmission processing, interference cancelation, and any other physical layer processing functions. Digital signal processor 208 may be structurally realized as hardware components (e.g., as one or more digitally-configured hardware circuits or FPGAs), software-defined components (e.g., one or more processors configured to execute program code defining arithmetic, control, and I/O instructions (e.g., software and/or firmware) stored in a non-transitory computer-readable storage medium), or as a combination of hardware and software components. In some aspects, digital signal processor 208 may include one or more processors configured to retrieve and execute program code that defines control and processing logic for physical layer processing operations. In some aspects, digital signal processor 208 may execute processing functions with software via the execution of executable instructions. In some aspects, digital signal processor 208 may include one or more dedicated hardware circuits (e.g., ASICs, FPGAs, and other hardware) that are digitally configured to specific execute processing functions, where the one or more processors of digital signal processor 208 may offload certain processing tasks to these dedicated hardware circuits, which are known as hardware accelerators. Exemplary hardware accelerators can include Fast Fourier Transform (FFT) circuits and encoder/decoder circuits. In some aspects, the processor and hardware accelerator components of digital signal processor 208 may be realized as a coupled integrated circuit.

Communication device 200 may be configured to operate according to one or more radio communication technologies. Digital signal processor 208 may be responsible for lower-layer processing functions (e.g., Layer 1/PHY) of the radio communication technologies, while protocol controller 210 may be responsible for upper-layer protocol stack functions (e.g., Data Link Layer/Layer 2 and/or Network Layer/Layer 3). Protocol controller 210 may thus be responsible for controlling the radio communication components of communication device 200 (antenna system 202, RF transceiver 204, and digital signal processor 208) in accordance with the communication protocols of each supported radio communication technology, and accordingly may represent the Access Stratum and Non-Access Stratum (NAS) (also encompassing Layer 2 and Layer 3) of each supported radio communication technology. Protocol controller 210 may be structurally embodied as a protocol processor configured to execute protocol stack software (retrieved from a controller memory) and subsequently control the radio communication components of communication device 200 to transmit and receive communication signals in accordance with the corresponding protocol stack control logic defined in the protocol software. Protocol controller 210 may include one or more processors configured to retrieve and execute program code that defines the upper-layer protocol stack logic for one or more radio communication technologies, which can include Data Link Layer/Layer 2 and Network Layer/Layer 3 functions. Protocol controller 210 may be configured to perform both user-plane and control-plane functions to facilitate the transfer of application layer data to and from radio communication device 200 according to the specific protocols of the supported radio communication technology. User-plane functions can include header compression and encapsulation, security, error checking and correction, channel multiplexing, scheduling and priority, while control-plane functions may include setup and maintenance of radio bearers. The program code retrieved and executed by protocol controller 210 may include executable instructions that define the logic of such functions.

Communication device 200 may also include application processor 212 and memory 214. Application processor 212 may be a CPU, and may be configured to handle the layers above the protocol stack, including the transport and application layers. Application processor 212 may be configured to execute various applications and/or programs of communication device 200 at an application layer of communication device 200, such as an operating system (OS), a user interface (UI) for supporting user interaction with communication device 200, and/or various user applications. The application processor may interface with baseband modem 206 and act as a source (in the transmit path) and a sink (in the receive path) for user data, such as voice data, audio/video/image data, messaging data, application data, basic Internet/web access data, etc. In the transmit path, protocol controller 210 may therefore receive and process outgoing data provided by application processor 212 according to the layer-specific functions of the protocol stack, and provide the resulting data to digital signal processor 208. Digital signal processor 208 may then perform physical layer processing on the received data to produce digital baseband samples, which digital signal processor may provide to RF transceiver 204. RF transceiver 204 may then process the digital baseband samples to convert the digital baseband samples to analog RF signals, which RF transceiver 204 may wirelessly transmit via antenna system 202. In the receive path, RF transceiver 204 may receive analog RF signals from antenna system 202 and process the analog RF signals to obtain digital baseband samples. RF transceiver 204 may provide the digital baseband samples to digital signal processor 208, which may perform physical layer processing on the digital baseband samples. Digital signal processor 208 may then provide the resulting data to protocol controller 210, which may process the resulting data according to the layer-specific functions of the protocol stack and provide the resulting incoming data to application processor 212. Application processor 212 may then handle the incoming data at the application layer, which can include execution of one or more application programs with the data and/or presentation of the data to a user via a user interface.

Memory 214 may embody a memory component of communication device 200, such as a hard drive or another such permanent memory device. Although not explicitly depicted in FIG. 2, the various other components of communication device 200 shown in FIG. 2 may additionally each include integrated permanent and non-permanent memory components, such as for storing software program code, buffering data, etc.

In accordance with some radio communication networks, terminal devices 102 and 104 may execute mobility procedures to connect to, disconnect from, and switch between available network access nodes of the radio access network of radio communication network 100. As each network access node of radio communication network 100 may have a specific coverage area, terminal devices 102 and 104 may be configured to select and re-select\available network access nodes in order to maintain a strong radio access connection with the radio access network of radio communication network 100. For example, terminal device 102 may establish a radio access connection with network access node 110 while terminal device 104 may establish a radio access connection with network access node 112. In the event that the current radio access connection degrades, terminal devices 102 or 104 may seek a new radio access connection with another network access node of radio communication network 100; for example, terminal device 104 may move from the coverage area of network access node 112 into the coverage area of network access node 110. As a result, the radio access connection with network access node 112 may degrade, which terminal device 104 may detect via radio measurements such as signal strength or signal quality measurements of network access node 112. Depending on the mobility procedures defined in the appropriate network protocols for radio communication network 100, terminal device 104 may seek a new radio access connection (which may be, for example, triggered at terminal device 104 or by the radio access network), such as by performing radio measurements on neighboring network access nodes to determine whether any neighboring network access nodes can provide a suitable radio access connection. As terminal device 104 may have moved into the coverage area of network access node 110, terminal device 104 may identify network access node 110 (which may be selected by terminal device 104 or selected by the radio access network) and transfer to a new radio access connection with network access node 110. Such mobility procedures, including radio measurements, cell selection/reselection, and handover are established in the various network protocols and may be employed by terminal devices and the radio access network in order to maintain strong radio access connections between each terminal device and the radio access network across any number of different radio access network scenarios.

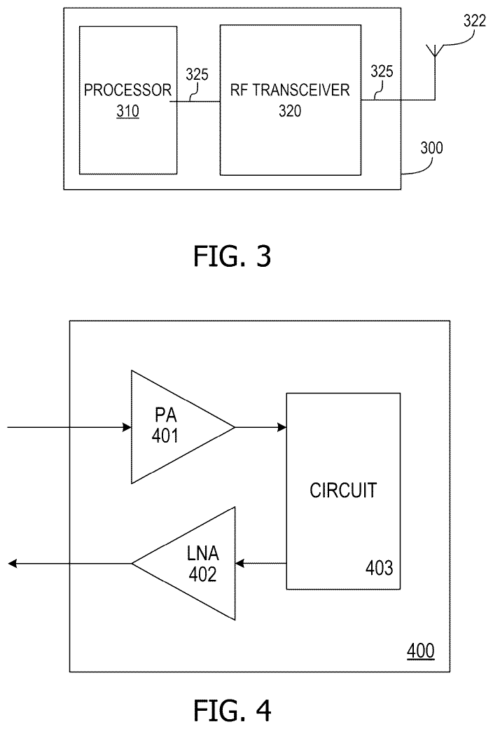

FIG. 3 shows an exemplary illustration of various communication elements of an apparatus for a wireless communication device (e.g. the communication device 200). The apparatus 300 may include processing circuitry 310 (e.g. the baseband modem 206, the application processor 212) that may direct and manage communication operations of the apparatus 300 according to one or more radio communication protocols, and may control transmission/reception of communication signals over at least one or more antenna 322 via an RF transceiver 320. The processing circuitry 310 may include an interface to the RF transceiver 320. The RF transceiver 320 may include at least one RF-chain to process the communication signals associated with the antenna 322 respectively. The apparatus 300 may include the antenna 322, or the apparatus 300 may include an antenna interface couplable to the antenna 322. It is to be noted that the apparatus 300 is depicted as being couplable to the antenna 322, but the apparatus 300 may be couplable to a plurality of antennas, and thereby the RF transceiver 320 may include a plurality of RF-chains, each RF-chain may process communication signals for a respective antenna. The apparatus 300 may transmit and receive radio communication signals with the antenna 322. The apparatus 300 may act as an RF transmitter (e.g. RF transmit circuit) to transmit radio communication signals and it may also act as an RF receiver (e.g. RF receive circuit) to receive radio communication signals. In accordance with various aspects described herein, amplifiers referred to in accordance with aspects described in FIG. 3 (e.g. PAs) may include aspects described in this disclosure, e.g. one or more amplifier circuitries.

The processing circuitry 310 may include, or may be implemented, partially or entirely, by circuit and/or logic, e.g., a processor including circuit and/or logic, a memory circuit and/or a logic, which may be configured to manage radio communication operations. The processing circuitry 310 may be configured to communicate with an external main processor (e.g. a host processor, a central processing unit (CPU), a system on chip (SoC)) of the wireless communication device including the apparatus 300 via a designated interface that is coupled to the main processor. In some examples, the processing circuitry 310 may be the main processor of the wireless communication device. The processing circuitry 310 may also access the main memory of the respective wireless communication device via the designated interface. The processing circuitry 310 may further include an interface to the RF transceiver 320.

The processing circuitry 310 may include a digital signal processor (e.g. the digital signal processor 208). The digital signal processor 208 may be configured to perform one or more of error detection, forward error correction encoding/decoding, channel coding, and interleaving, channel modulation/demodulation, physical channel mapping, radio measurement and search, frequency and time synchronization, antenna diversity processing, power control, and weighting, rate matching/de-matching, retransmission processing, interference cancelation, and any other physical layer processing functions.

The processing circuitry 310 may include a modem configured to process baseband signals received from/sent to the antenna 322 via a communication path 325 including a respective RF-chain. In various examples, the interface to the RF transceiver 320 of the processing circuitry 310 may be configured to couple the processing circuitry 310 to the communication path 325. Accordingly, the processing circuitry 310 may include Media-Access Control (MAC) circuit and/or logic, Physical Layer (PHY) circuit and/or logic, baseband (BB) circuit and/or logic, a BB processor, a BB memory, Application Processor (AP) circuit and/or logic, an AP processor, an AP memory, and/or any other circuit and/or logic. By way of example, the processing circuitry 310 can perform baseband processing on the digital baseband signals to recover data included in wireless data transmissions.

The processing circuitry 310 may control and/or arbitrate transmit and/or receive functions of the apparatus 300, and perform one or more baseband processing functions (e.g., media access control (MAC), encoding/decoding, modulation/demodulation, data symbol mapping, error correction, etc.). The processing circuitry 310 may be configured to provide control functions to the RF transceiver 320 (e.g. to the RF-chain to control and/or arbitrate transmitting and/or receiving radio communication signals). In aspects, functions of processing circuitry 310 can be implemented in software and/or firmware executing on one or more suitable programmable processors, and may be implemented, for example, in a field programmable gate array (FPGA), application specific integrated circuit (ASIC), etc. In various examples, the interface to the RF transceiver 320 of the processing circuitry 310 may be configured to couple processing circuitry to the RF transceiver to provide communication in-between.

The RF transceiver 320 may provide RF processing of communication signals conveyed via a communication path within a respective RF-chain to transmit radio communication signals via a respective antenna based on signals (e.g. baseband communication signals, digital signals) received from the processing circuitry 310 over the communication path. The RF transceiver 320 may provide RF processing of communication signals conveyed via the communication path 325 to receive radio communication signals via the antenna 322 and provide signals to the processing circuitry 310 over the communication path 325. The processing circuity 310 may be configured to control operations of the RF transceiver 320. The RF transceiver 320 may include a receive path to provide RF processing to receive radio communication signals received from the antenna 322, and a transmit path to provide RF processing to transmit radio communication signals transmitted via the antenna 322.

In a receive (RX) path, The RF transceiver 320 may receive analog radio frequency signals from the antenna 322 via the communication paths 325 and perform analog and digital RF front-end processing on the analog radio frequency signals to produce digital baseband samples (e.g., In-Phase/Quadrature (IQ) samples) to provide to the processing circuitry 310. In various examples, RF transceiver 320 may include two RF-chains per antenna clement, each RF-chain may be designated for a particular polarization. The RF transceiver 320 may include analog and digital reception components including amplifiers (e.g., Low Noise Amplifiers (LNAs)), filters, RF demodulators (e.g., RF IQ demodulators)), and analog-to-digital converters (ADCs), which RF transceiver 320 may utilize to convert the received radio frequency signals to digital baseband samples.

In a transmit (TX) path, the RF transceiver 320 may receive digital baseband samples from processing circuitry 310 and perform analog and digital RF front-end processing on the digital baseband samples to produce analog radio frequency signals to be provided to the antenna 322 via the communication paths 325 for radio transmission. The RF transceiver 320 may thus include analog and digital transmission components including amplifiers (e.g., Power Amplifiers (PAs), filters, RF modulators (e.g., RF IQ modulators), and digital-to-analog converters (DACs), which the RF transceiver 320 may utilize to mix the digital baseband samples received from processing circuitry 310 and produce respective analog radio frequency signals for radio transmission by the antenna 322. In some aspects, the processing circuitry 310 may control the radio transmission and reception of the RF transceiver 320, including specifying the transmit and receive radio frequencies for the operation of the RF transceiver 320. In some examples, the RF transceiver 320 may include a DTX architecture. In some examples, operations associated with the digital front-end may be provided by the processing circuitry 310 as well, or in other words, the processing circuitry 310 may include the digital front-end.

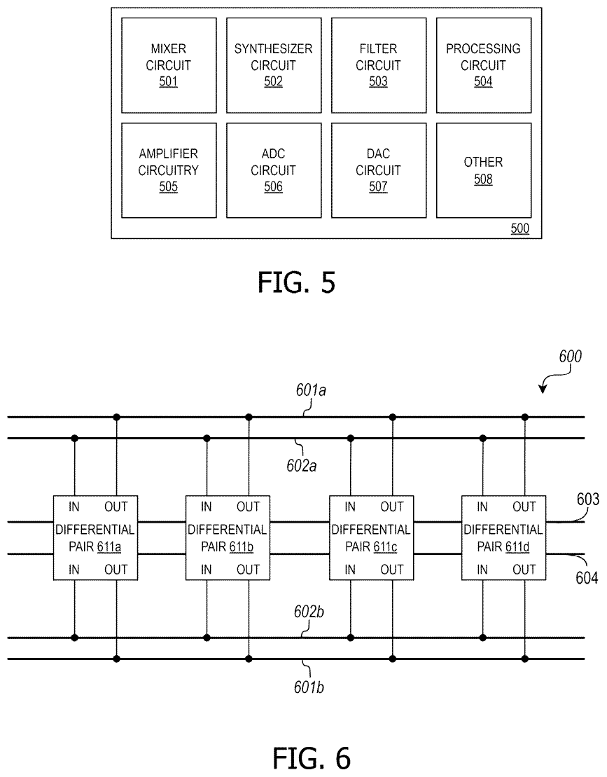

FIG. 4 shows schematically a block diagram of an example radio frequency (RF) front end circuit 400 that may be implemented in a radio communication device including a transmitter and a receiver, which an RF-chain of an RF transceiver (e.g. the RF transceiver 320) may include. A TX path of the radio frequency (RF) front end circuit 400 may include a PA 401 for amplifying input radio frequency (RF) signals. The RF front end circuit 400 may further include an RX path. The RX path of the radio frequency (RF) front end circuit 400 may include an LNA 402 to amplify received radio frequency (RF) signals and provides the amplified received radio frequency (RF) signals as an output. One or more filters may be included to generate suitable radio frequency (RF) signals for transmission and reception. In addition, the radio frequency (RF) front end circuit 400 may include other components or circuits 403, such as, for example, a tuner or a matching network, switches, multiplexers, and/or other circuits for coupling the radio frequency (RF) front end circuit 400 to an antenna, in order to form an RF transceiver. In addition, other components may be included to support both transmit and receive functions. In accordance with various aspects described herein, amplifiers referred to in accordance with aspects described in FIG. 4 (e.g. PAs) may include aspects described in this disclosure, e.g. one or more amplifier circuitries.

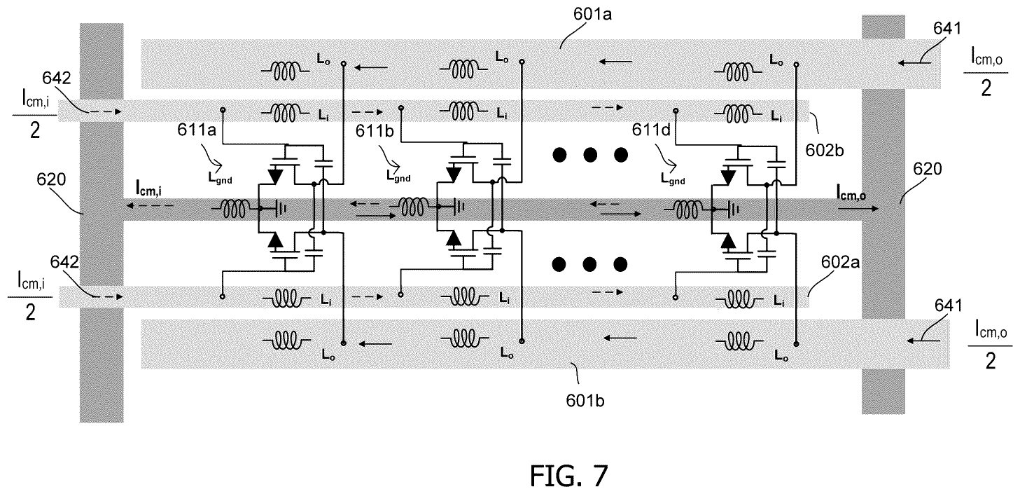

FIG. 5 shows schematically an example of a RF transceiver circuitry 500 which a radio communication device may include. The RF transceiver circuitry 500 can include components such as a mixer circuit 501, a synthesizer circuit 502 (e.g., local oscillator), a filter circuit 503 (e.g., baseband filter), a processing circuit 504, an amplifier circuitry 505, an analog-to-digital converter (ADC) circuit 506, a digital-to-analog (DAC) circuit 507, and other suitable digital front end (DFE) components 508, to name a few. The processing circuit 504 may include a processor, which may include a time-domain and/or frequency domain processor(s)/components in at least one example.

Accordingly, the exemplary radio frequency (RF) front end circuit 400 referred with respect to FIG. 4 may be provided by a combination of the circuits provided with respect to the schematic representation of the example of the RF transceiver circuitry 500. It should be noted that any of these circuits may include a plurality of circuits configured to provide the functionality. For example, the amplifier circuitry 505 may include a plurality of amplifier circuits or amplifiers as described in this disclosure.

The other components 508 may include logic components, modulation/demodulation elements, and an interface circuit for interfacing with another component, e.g., an SoC, or a modem. Digital front end components may include any suitable number and/or type of components configured to perform functions known to be associated with digital front ends.

The digital front end may include digital processing circuit, portions of processing circuitry, one or more portions of an on-board chip having dedicated digital front end functionality (e.g., a digital signal processor), etc. The digital front end components may selectively perform specific functions based upon the operating mode of the RF transceiver circuitry 500. The digital front end components may facilitate beamforming.

Digital front end components may also include other components associated with data transmission such as, for instance, transmitter impairment correction such as LO correction, DC offset correction, IQ imbalance correction, and ADC skew, digital pre-distortion (DPD) calculation, correction factor (CF) calculation, and pre-emphasis (pre. emp.) calculation. To provide additional examples, the digital front end components may facilitate or perform receiver or transmitter digital gain control (DGC), up-sampling, down-sampling, zero crossing detection algorithms, phase modulation, perform beam management, digital blocker cancellation, received signal strength indicator (RSSI) measurements, DPD and calibration accelerators, test signal generation, etc.

The RF transceiver circuitry 500 may include a receive signal path which may include the mixer circuit 501, the amplifier circuitry 505, and the filter circuit 503. In some aspects, the transmit signal path of the RF transceiver circuitry 500 may include the filter circuit 503, the amplifier circuitry 505, and the mixer circuit 501. The radio communication circuit may also include the synthesizer circuit 502 to synthesize a frequency signal for use by the mixer circuit 501 of the receive signal path and the transmit signal path. The mixer circuit 501 of the receive signal path may be configured to down-convert radio frequency (RF) signals received based on the synthesized frequency provided by synthesizer circuit 502.

In some aspects, the output baseband signals and the input baseband signals may be digital baseband signals. In such aspects, the RF transceiver circuitry 500 may include the analog-to-digital converter (ADC) circuit 506 and the digital-to-analog converter (DAC) circuit 507.

The RF transceiver circuitry 500 may also include a transmit signal path (Tx path) which may include a circuit to up-convert baseband signals provided by a modem and provide radio frequency (RF) output signals for transmission. In some aspects, the receive signal path of the RF transceiver circuitry 500 may include the mixer circuit 501, the amplifier circuitry 505, and the filter circuit 503. In some aspects, the transmit signal path of the RF transceiver circuitry 500 may include the filter circuit 503, the amplifier circuitry 505, and the mixer circuit 501. The RF transceiver circuitry 500 may include synthesizer circuit 502 to synthesize a frequency signal for use by the mixer circuit 501 of the receive signal path and the transmit signal path. The mixer circuit 501 of the receive signal path may be configured to received down-convert radio frequency (RF) signals based on the synthesized frequency provided by synthesizer circuit 502.

Amplifier circuitry 505 may be configured to amplify the down-converted signals, and filter circuit 503 may be a low-pass filter (LPF) or band-pass filter (BPF) configured to remove unwanted signals from the down-converted signals to generate output baseband signals. Output baseband signals may be provided to another component, e.g., a modem, for further processing. In some aspects, the output baseband signals may be zero-frequency baseband signals, although this is not a requirement. In accordance with various aspects described herein, amplifier circuitry 505 may be an amplifier circuitry and may include aspects described in this disclosure. Illustratively, the amplifier circuitry may include one or more NDP arrays as PAs.

The mixer circuit 501 for a receive signal path may include passive mixers, although the scope of this disclosure is not limited in this respect. In some aspects, the mixer circuit 501 for a transmit signal path may be configured to up-convert input baseband signals based on the synthesized frequency provided by the synthesizer circuit 502 to generate radio frequency (RF) output signals. In various aspects, amplifier circuitry 505 may be configured to amplify the radio frequency (RF) output signals, and filter circuit 503 may be a low-pass filter (LPF) or band-pass filter (BPF) configured to remove unwanted signals from the up-converted signals to provide communication signals to be transmitted. The radio frequency (RF) communication signals may be provided to another component, to an antenna port or an antenna.

In some aspects, the mixer circuit 501 of the receive signal path and the mixer circuit 501 of the transmit signal path may include two or more mixers and may be arranged for quadrature down conversion and up conversion, respectively. In some aspects, the mixer circuit 501 of the receive signal path and the mixer circuit 501 of the transmit signal path may include two or more mixers and may be arranged for image rejection (e.g., Hartley image rejection). In some aspects, the mixer circuit 501 of the receive signal path and the mixer circuit 501 may be arranged for direct down conversion and direct up conversion, respectively. In some aspects, the mixer circuit 501 of the receive signal path and the mixer circuit 501 of the transmit signal path may be configured for super-heterodyne operation.

In some dual-mode aspects, a separate radio IC circuit may be provided for processing signals for each spectrum, although the scope of this disclosure is not limited in this respect.

In some aspects, the synthesizer circuit 502 may be a fractional-N synthesizer or a fractional N/N+1 synthesizer, although the scope of the aspects is not limited in this respect as other types of frequency synthesizers may be suitable. For example, synthesizer circuit 502 may be a delta-sigma synthesizer, a frequency multiplier, or a synthesizer including a phase-locked loop with a frequency divider.

The synthesizer circuit 502 may be configured to synthesize an output frequency for use by the mixer circuit 501 of the RF transceiver circuitry 500 based on a frequency input and a divider control input. The synthesizer circuit 502 may be a fractional N/N+1 synthesizer.

Frequency input may be provided by a voltage-controlled oscillator (VCO), although that is not a requirement. Divider control input may be provided by a processing component of the RF transceiver circuitry 500 or may be provided by any suitable component, such as an external component like a modem. For example, the modem may provide a divider control input depending on the desired output frequency. A divider control input (e.g., N) may be determined from a look-up table based on a channel indicated by an external component.

Synthesizer circuit 502 of the RF transceiver circuitry 500 may include a divider, a delay-locked loop (DLL), a multiplexer, and a phase accumulator. The divider may be a dual modulus divider (DMD) and the phase accumulator may be a digital phase accumulator. The DMD may be configured to divide the input signal by either N or N+1 (e.g., based on a carry out) to provide a fractional division ratio. The DLL may include a set of cascaded, tunable, delay elements, a phase detector, a charge pump, and a D-type flip-flop. The delay elements may be configured to break a VCO period up into No equal packets of phase, where Nd is the number of delay elements in the delay line. In this way, the DLL provides negative feedback to help ensure that the total delay through the delay line is one VCO cycle.

Synthesizer circuit 502 may be configured to generate a carrier frequency as the output frequency, while in an alternative, the output frequency may be a multiple of the carrier frequency (e.g., twice the carrier frequency, four times the carrier frequency) and used in conjunction with quadrature generator and divider circuit to generate multiple signals at the carrier frequency with multiple different phases with respect to each other. The output frequency may be a LO frequency (fLO). In some aspects, the RF transceiver circuitry 500 may include an IQ/polar converter.

While the RF transceiver circuitry 500 described herein include traditional super-heterodyning schemes or architectures, other types of transceiver or transmitter architectures and schemes may be used. The RF transceiver circuitry 500 may include components to implement a near zero IF scheme, a Direct Conversion scheme, or a digital transmission scheme, such as, for example, a Digital IQ transmission, a Digital Polar transmission, and the like.

The RF transceiver circuitry 500 may include a transmit path that includes or implements a direct digital transmitter (DDT). That is, a DDT may include a digital signal processor, an RF digital-to-analog converter (RFDAC), an RF filter/antenna coupler. Further, a DDT may be implemented with or without an IQ-mixer. In general, an RF-DAC may be included on an RFIC to convert digital input into an RF signal. A DDT may include other digital components such as numerically controlled oscillator (NCO) and digital mixers for shifting an input signal to the desired frequency. The use of a DDT can reduce the number of analog components needed in the transmitter or transmit path. For example, analog LOs, analog filters, analog mixers, and etc., may be eliminated from the RFIC when a direct digital transmitter such as DDT is employed. Further, the use of a digital transmitter or digital transmission schemes may bring energy savings and efficiencies.

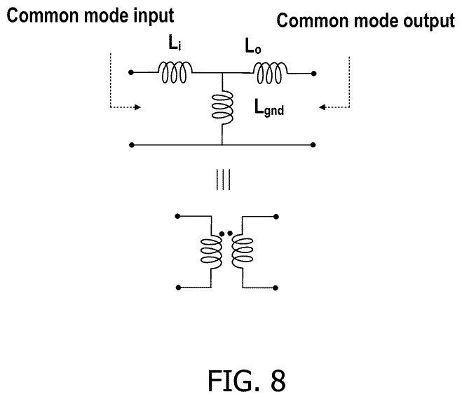

FIG. 6 shows schematically an example of an amplifier circuitry in accordance with various aspects provided herein. The amplifier circuitry 600 may include a plurality of differential amplifiers 611a-d, each differential amplifier including a circuit including pair of amplifiers configured in a differential configuration (which may be referred to as a differential pair amplifier). The amplifier circuitry 600 may include connections to supply differential input signals to the plurality of differential pair amplifiers 611a-d (i.e. input connections) and to supply differential output signals of the plurality of differential pair amplifiers 611a-d to one or more output terminals of the amplifier circuitry 600.

As illustrated in this example, the amplifier circuitry 600 may include differential input connections 602a-b configured to supply differential input signals received by the amplifier circuitry 600 to differential pair amplifiers 611a-d. Illustratively, first active device (e.g. transistor) of each differential pair amplifier 611a-d may receive a first input signal from one of the differential input connections 602a-b and second active device (e.g. transistor) of each differential pair amplifier 611a-c may receive a second input signal, that is a differential pair of the first input signal, from another one of the differential input connections 602a-b.

Illustratively, the differential input connections 602a-b may include a positive input connection and a negative input connection. Positive input terminals of the differential pair amplifiers 611a-d may be coupled to the positive input connection and negative input terminals of the differential pair amplifiers 611a-d may be coupled to the negative input connection.

Furthermore, the amplifier circuitry 600 may include differential output connections 601a-b configured to supply differential output signals received from the differential pair amplifiers 611a-d to an output terminal. Illustratively, first active device (e.g. transistor) of each differential pair amplifier 611a-d may output a first output signal to one of the differential output connections 601a-b and second active device (e.g. transistor) of each differential pair amplifier 611a-d may output a second output signal, that is a differential pair of the first output signal, from another one of the differential output connections 601a-b.

In accordance with various aspects provided herein, the plurality of differential pair amplifiers 611a-d may be considered as an array. These representations may be used throughout this disclosure to simply refer to respective differential pair amplifiers as described herein.

The differential pair amplifiers 611a-d may be coupled to (i.e. between) the differential output connections 601a-b and the differential input connections 602a-b. Illustratively, the differential output connections 601a-b may be disposed on a plane extending in one direction. The differential input connections 602a-b may be disposed on the plane extending in the same direction, in a manner that is parallel or substantially parallel to the differential output connections 601a-b, between the differential output connections 601a-b. The differential pair amplifiers 611a-d may also be disposed on the plane extending the same direction, in a manner that is parallel or substantially parallel to the differential output connections 601a-b and/or the differential input connections 602a-b, between the differential output connections 601a-b and the differential input connections 602a-b.

The amplifier circuitry 600 may further include power supply connections 603, 604 to power the differential pair amplifiers 611a-d. For example, in an n-channel metal oxide semiconductor (NMOS)-based differential pair, the sources of the NMOS transistors may be connected together, while the drains of the NMOS differential pair transistors may be connected through load devices like resistors or PMOS transistors to the positive voltage supply V_{DD} (e.g. through inductors or transformers configured for mm Wave frequency) The sources of the NMOS transistors may further be connected to the ground. The gates of the NMOS differential pair transistors may be connected to the differential input connections 602a-b, with one NMOS transistor connected to the positive input connection (e.g. 602a) and the other connected to the negative input connection (e.g. 602b). The drains of the NMOS differential pair transistors may also be connected to the differential output connections 601a-b, with one NMOS transistor connected to the positive output connection (e.g. 601a) and the other connected to the negative output connection (e.g. 601b).

In a p-channel metal oxide semiconductor (PMOS)-based differential pair, the sources of the PMOS transistors may be connected together, while the drains of the PMOS differential pair transistors may be connected through load devices like resistors or NMOS transistors (e.g. and/or to inductor or transformer as load) to a negative voltage supply V_{SS} or ground. The sources of the PMOS transistors may further be connected to the positive voltage supply V_{DD}. The gates of the PMOS differential pair transistors would be connected to the differential input connections 602a-b, with one transistor connected to the positive input connection (e.g. 602a) and the other connected to the negative input connection (e.g. 602b). The drains of the PMOS differential pair transistors would also be connected to the differential output connections 601a-b, with one transistor connected to the positive output connection (e.g. 601a) and the other connected to the negative output connection (e.g. 601b).

Due to their potential deployment within close proximity, and their possible parallel (or substantially parallel) placement, in particular considering high frequencies of mmWave-subTHz signals, a considerable magnetic and electric coupling may occur between input and output connections, or other components and structures of the amplifier circuitry 600, within close proximity. Through magnetic coupling in-between, magnetic feedback currents may be generated within the amplifier circuitry 600.

A magnetic coupling coefficient may refer to a measure of magnetic coupling between two conductors or components. The magnetic coupling coefficient may have a magnitude (e.g. between 0 and 1), representing the strength of the magnetic coupling, and a polarity (i.e. a positive or negative sign) that is indicative of the polarity or direction of the induced currents or the phase relationship between the two conductors or components. Illustratively, a higher magnitude coupling coefficient indicates a stronger magnetic interaction between the two conductors or components, while the polarity may indicate the direction of the generated (i.e. induced) currents.

Within the context of NDP arrays, an active core of a PA (e.g. mmWave PA) may include capacitively neutralized NDP cells as described herein through which an NDP array is formed for a larger active core to produce a large output power, which may be based on the number of differential pair amplifiers used within the NDP array. Differential pair amplifiers may include neutralizing capacitors, which may be formed by interconnect parasitic or directly with active devices, to cancel the electric or capacitive feedback from output to input created by active device capacitance (e.g. drain-gate capacitance). This neutralization may be effective, in particular, when active devices are driven differentially, which may improve gain, stability factor, robustness to PVT.

In high power PA designs, higher output power may be achieved using a larger device size that is formed by arraying a unit cell sized NDP cell to form one or two dimensional physical array (1×N, 2×N, . . . . N×N) in a designated layout. Depending upon operating frequency and size of the array, the distributed effects associated with parasitic inductance and mutual inductance on both input (gate) and output (drain) signal routing can be significant and may need a careful modeling using both electromagnetic and parasitic extraction tools. Traditionally, it is common for these inductive effects to be ignored for an NDP design but this may pose a significant design risk at mmWave and subTHz frequencies. Since each NDP unit cell may include a local neutralization canceling out electric feedback associated with gate-drain capacitance of active devices, the magnetic component of the feedback may become dominating effect for the degradation in stability and gain for a large NDP array. Such cancelling out may be specific to differential mode and common-mode neutralization may not be possible through such implementations. To ensure stability, the array size may be often limited to reduce the amount of magnetic feedback and but this results in a reduced output power.

In the context of the amplifier circuitry 600, common mode and differential mode may refer to two different types of input signals. Common mode signals may include signals present on both differential input connections 602a-b and differential output connections 601a-b of the amplifier circuitry 600 (and correspondingly at each input and output terminals of each differential amplifier pairs 611a-d) with the same amplitude and phase. Differential mode signals may include desired input and output signals that may have equal amplitude but opposite polarity at the respective input or output connections. In differential operation mode, the amplifier circuitry may ideally reject common mode signals and may have a common mode gain of zero, however, due to component mismatches and/or other non-ideal matters, the common mode signals may be present within the amplifier circuitry 600. In some examples, the amplifier circuitry 600 may be deliberately configured to operate in common mode.

In a broader presentation, the common-mode voltage may refer to the average voltage present at the positive and negative differential input connections 602a-b and at the positive and negative differential output connections 601a-b in the amplifier circuitry. In a further representation, an input common voltage may refer to the average voltage present at the positive and negative differential input connections 602a-b, and an output common voltage may refer to the average voltage present at the positive and negative differential output connections 601a-b. In more detail, a respective input common voltage may refer to a respective average voltage present at a respective positive input terminal (i.e. connected to the positive input connection of the differential input connections (e.g. 602a) and a respective negative input terminal (i.e. connected to the negative input connection of the differential input connections (e.g. 602b)) of each differential pair amplifier 611a-d. Similarly, a respective output common voltage may refer to a respective average voltage present at the positive output terminal (i.e. connected to the positive output connection of the differential output connections (e.g. 601a) and the negative output terminal (i.e. connected to the negative output connection of the differential output connections (e.g. 601b)) of each differential pair amplifier 611a-d.

Ideally, an ideal differential pair amplifier configured for differential operation, such as differential pair amplifiers (611-ad) of the amplifier circuitry 600, may be expected to only amplify the differential-input signals received from the differential input connections 602a-b and reject the common-mode voltage, which may be referred to as common-mode rejection. In accordance with various aspects provided herein, the amplifier circuitry 600 may handle such common-mode voltages, as common-mode stability may be important as described herein. The differential pair amplifiers 611a-d in the amplifier circuitry 600 can effectively reject these high common-mode voltages while still amplifying the desired differential-mode signal. In some examples, the amplifier circuitry 600 may operate deliberately in common mode by providing common mode input signals.

In this context, common mode currents may refer to currents that may flow due to presence of the common mode voltage as described herein. As described with respect to the common-mode voltage from different representations directed to the amplifier circuitry 600 itself from the broader representation, the common-mode currents of the amplifier circuitry 600 may flow through the differential input connections 602a-b and the differential output connections 601a-b. In the further representation, input common-mode currents may to refer to common-mode currents flowing through the positive and negative differential input connections 602a-b, and output common-mode currents may refer to common mode currents flowing through the positive and negative differential output connections 601a-b.

In more detail, respective input common-mode currents may refer to respective common-mode currents flowing through a respective positive input terminal (i.e. connected to the positive input connection of the differential input connections (e.g. 602a) and a respective negative input terminal (i.e. connected to the negative input connection of the differential input connections (e.g. 602b)) of each differential pair amplifier 611a-d. Similarly, respective output common mode currents may refer to respective common mode currents flowing through a respective positive output terminal (i.e. connected to the positive output connection of the differential output connections (e.g. 601a) and a respective negative output terminal (i.e. connected to the negative output connection of the differential output connections (e.g. 601b)) of each differential pair amplifier 611a-d. Such currents can arise due to various factors, such as input bias currents of the transistors, mismatches in the input circuitry, or external interference coupled to the input connections 602a-b.

While the above-mentioned common mode currents flow through corresponding terminals and connections, the amplifier circuitry 600 may include a return path for common-mode currents, which may be referred to herein as common mode return current connection or connections, and sometimes as return current connection. The return current connection or the common mode return current connection may refer to a connection through which the common-mode currents flows through the differential pair amplifiers 611a-d (e.g. flows through the transistors of the differential pair amplifiers 611a-d towards out of the differential pair amplifiers 611a-d respectively). In a differential architecture, as described with respect to the amplifier circuitry 600, the amplifier circuitry may be configured such that the common-mode currents from the differential pair amplifiers 611a-d may flow towards the return current connection, which may be coupled to the ground or to the appropriate power supply. Illustratively, the amplifier circuitry may include a low-impedance path between the common-mode output voltage and the desired reference voltage, such as ground or V_{DD}/2.

Illustratively, for the NMOS-based differential pair amplifiers as described herein (i.e. differential pair amplifiers 611a-d being NMOS-based differential pair amplifiers), the return current connection may be connected to (and/or may include) the ground terminal. The sources of the NMOS transistors in each differential pair 611a-d may be connected together and also may be coupled to the ground. Illustratively, for NMOS-based scenario, the return current connection may be the ground connection. Correspondingly, any common-mode currents flowing through the NMOS differential pair may flow to the ground through the return current connection.

Illustratively, for PMOS-based differential pair amplifiers as described herein (i.e. differential pair amplifiers 611a-d being PMOS-based differential pair amplifiers), the return current connection may be connected to (and/or may include) the positive supply terminal (V_{DD})). In this case, the sources of the PMOS transistors in each differential pair may be connected together and also may be coupled to the power supply configured to supply V_{DD}. Illustratively, for PMOS-based architecture, the return current connection may be the positive supply connection. Correspondingly, any common-mode currents flowing through the PMOS differential pair may flow to the positive supply through the return connection.

Correspondingly, each differential pair amplifier 611a-d may include a respective first transistor including a respective gate, a respective source, and a respective drain. Each differential pair amplifier 611a-d may further include a respective gate, a respective source, and a respective drain. The respective first transistor and the respective second transistor of each differential pair amplifier 611a-d may be provided in a common-source configuration. In other words, the respective source of the respective first transistor may be coupled to the respective source of the respective second transistor for each differential pair amplifier 611a-d. The amplifier circuitry 600 may further include a return current connection connected to the source of the respective first transistor and to the source of the respective second transistor of each differential pair amplifier 611a-d.

The common mode return current connection may include a non-conductive gap that may divide the return current connection into a first portion of the return current connection that is conductive to carry return currents and a second portion of the return current connection that is conductive to carry return currents. The non-conductive gap may cause the first portion and the second portion to be electrically separated from each other, such that return currents flowing through the first portion cannot flow into the second portion and return currents flowing through the second portion cannot flow into the first portion.

In accordance with various aspects described herein the term “non-conductive gap” may include an insulation layer. Illustratively, the insulation layer may be provided between the first portion of the return current connection and the second portion of the return current connection. The insulation layer may insulate the first portion from the second portion. All aspects described herein for the non-conductive gap may be applicable for the insulation layer, unless indicated otherwise. The term “insulation layer” may include a structure configured to electrically isolate different parts of the circuit, and in accordance with aspects described herein, it may be configured to electrically isolate the first portion of the return current connection from the second portion of the return current connection. The insulation layer may include (e.g. may be composed of) materials with high electrical resistance (i.e. non-conducting materials), such as air, silicone, plastic, glass, a physical gap between two portions, or polymers configured as such. The insulation layer may be applied in various forms. For example, the insulation layer may include a coating, a film, a deposited layer, a gap.

The presence of such non-conductive gap does not substantially affect the differential mode operation of the amplifier circuitry 600. However, the non-conductive gap provided between the first portion and the second portion of the return current connection may force corresponding common-mode currents to flow through the coupled source terminals of each differential amplifier pair 611a-d towards the return current connection, which may be referred to as common-mode return currents.

In this constellation, input common-mode return currents and output common-mode return currents may flow in the same direction. Input common-mode return currents may refer to input common mode currents flowing through the inputs (i.e. differential input connections 602a-b, and/or input terminals of each differential pair amplifier 611a-d) towards the return current connection, in particular, towards the respective portion of the return current connection, which may also be referred to as common-mode return currents associated with output signals. Output common-mode return currents may refer to output common-mode currents flowing through the outputs (i.e. differential output connections 601a-b, and/or output terminals of each differential pair amplifier 611a-d), which may also be referred to as common-mode return currents associated with output signals. It is to be noted that these common-mode return currents may also be represented as described above, via the broader representation, from the perspective of the amplifier circuitry 600 and/or each differential pair amplifier 611a-d. Correspondingly, the return current connection may be configured to conduct, for each differential pair amplifier 611a-d, input common-mode return currents and output common-mode return currents.

As described herein, the return current connection may be arranged, such that input common mode signals of each differential pair amplifier 611a-d flow through their respective transistors of the respective differential pair amplifiers 611a-d and output common mode signals of each differential pair amplifier 611a-d flow through their respective transistors of the respective differential pair amplifiers 611a-d. In this constellation, the input common mode signals and the output common mode signals may flow in the same direction, at least through their respective transistors and through the return current connection.

Accordingly, considering that each differential pair amplifier 611a-d may be associated with a respective magnetic coupling due to common-mode operation of the amplifier circuitry 600, which may be referred to as common-mode magnetic coupling to distinguish it from magnetic coupling generated through differential mode operation, the respective common-mode magnetic coupling coefficient associated with each differential pair amplifier 611a-d may be positive (i.e. greater than 0). Illustratively, the respective common-mode magnetic coupling coefficient may be defined between respective differential input connections 602a-b or differential input terminals of the respective differential pair amplifier 611a-d. The provision of the non-conductive gap within the return current connection may cause the common-mode coupling coefficients of all of the differential pair amplifiers to be positive.

In various aspects, each differential pair amplifier 611a-d may be an NDP forming an NDP array as the amplifier circuitry 600. In this constellation, each differential pair amplifier 611-ad may include at least one neutralizing component. For example, at least one neutralizing component for each differential pair amplifier 611a-d may include capacitors coupled to gate of the respective first transistor and the drain of the respective second transistor and to gate of the respective second transistor and the respective drain of the first transistor. The at least one neutralizing component is configured to neutralize the parasitic capacitance associated with the respective differential pair amplifier 611a-d.

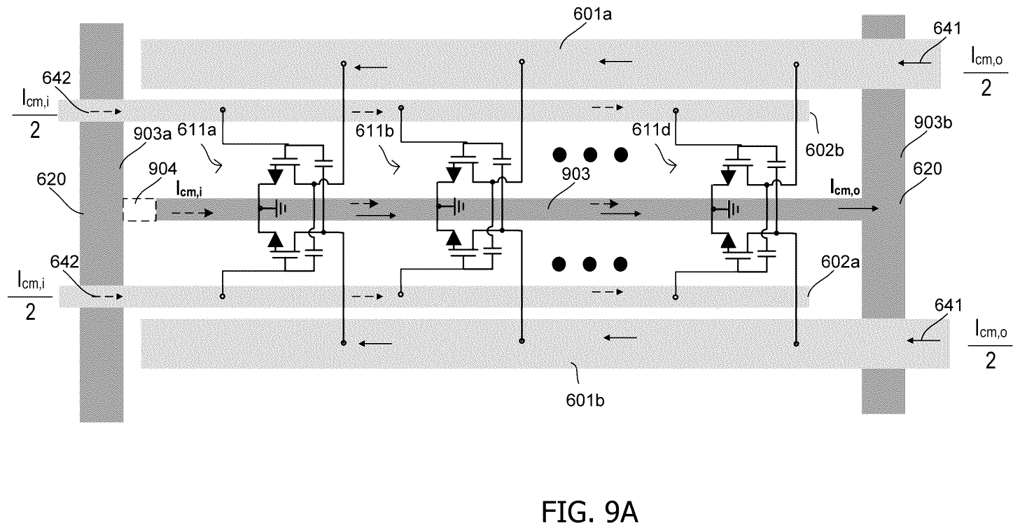

FIG. 7 shows schematically an exemplary illustration of an amplifier circuitry in accordance with various aspects of this disclosure. It is to be noted that various aspects described with respect to FIG. 6 apply to the amplifier circuitry described herein unless expressed otherwise. The amplifier circuitry may include the plurality of differential pair amplifiers 611a-d (611c is not depicted for brevity compared to FIG. 6), each represented in NMOS-based differential amplifier, the differential input connections 602a-b, the differential output connections 601a-b, and the ground connection 620.

The figure is depicted to represent common-mode operation of the amplifier circuitry. Correspondingly, the common mode operation may be modelled, such that the amplifier circuitry receives output common-mode currents 641, each represented as I_{cm,o}/2 and with solid line arrows and input common-mode currents 642, each represented as I_{cm,i}/2 and with dashed line arrows. It is to be noted that the amplifier circuitry illustrated herein does not include the non-conductive gap as described herein.

The amplifier circuitry may be a one-dimensional NDP array in its common-mode excitation. Lᵢ/Lₒ shown may represent the s input/output common mode inductance per unit NDP cell (i.e. respective differential pair amplifier including neutralizing component) on the gate and drain nodes respectively. In this constellation, the return common mode currents for both input (e.g. I_{cm,i}/2) and output (e.g. I_{cm,o}/2) may flow through a common source network that is depicted here as the ground connection coupled to the source terminals of each NMOS of each differential pair amplifier 611a-d and has an inductance per differential pair amplifier 611a-d of Lend. Correspondingly, the magnetic coupling between the respective input terminals of each differential pair amplifier 611a-d and the respective output terminals of each differential pair amplifier 611a-d may be dominated by the inductance Lend as the respective input common-mode return currents and the respective output common-mode return currents of the respective differential pair amplifier 611a-d may return through the same connection and may have coupling coefficient close to 1.

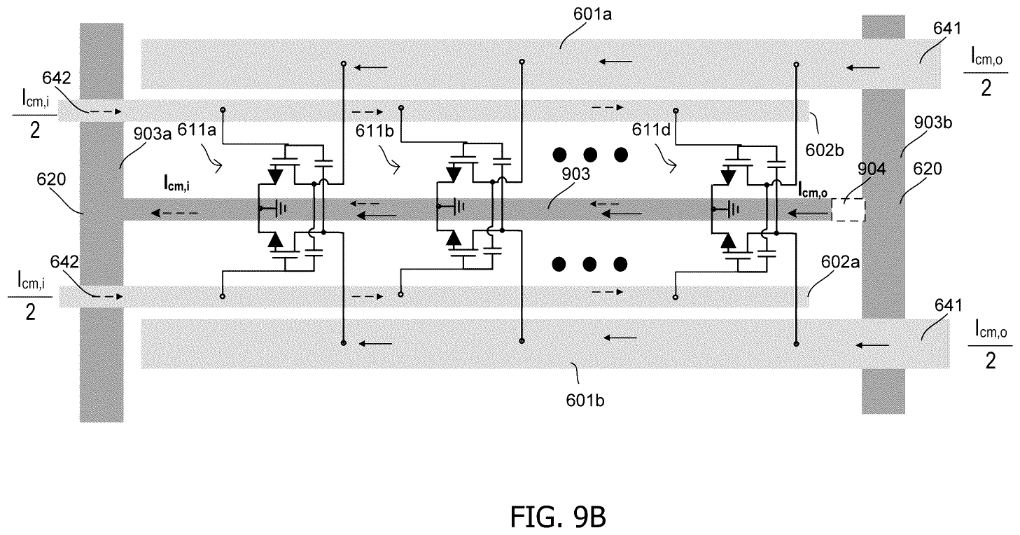

FIG. 8 shows an example illustration of a T model of a transformer. Illustratively, the magnetic coupling associated with a differential pair amplifier 611a-d may be represented for length of the differential pair with inductance on input, output, and mutual inductance, represented by Lᵢ, Lₒ, L_{gnd} in the same manner applicable to the amplifier circuitry described in accordance with FIG. 7. The L_{gnd} may be common to both input and output common mode currents and may set the magnetic feedback from output to input. The common source network may commonly be connected to ground from both input/output sides in order to obey electromigration limits on the metals and to also ensure well defined high frequency behavior, which may result in the respective input common mode return currents and the respective output common mode return currents to flow in opposite directions along this common source line, leading to a negative magnetic coupling.

Illustratively, the above-mentioned coupling can limit the common mode stability of a NDP array in PA. With an assessment involving NDP array including 20 differential pair amplifiers, modeled common mode inductance on the input and outputs are measured 1.027 pH and 1.584 pH respectively. The μ-factor stability may be characterized across the magnetic coupling coefficient (k) is varied from −1 to 1. A performed simulation shows that NDP array may be stable for k>0 and the stability improve with larger value of k. However, the PA can go unstable when k<0 and the magnitude of the coupling is sufficiently high. This k<0 condition may be obtained when the common source line is connected to the global supply plane on both sides, as previously mentioned, and as is often blindly done out of concern for reliability.

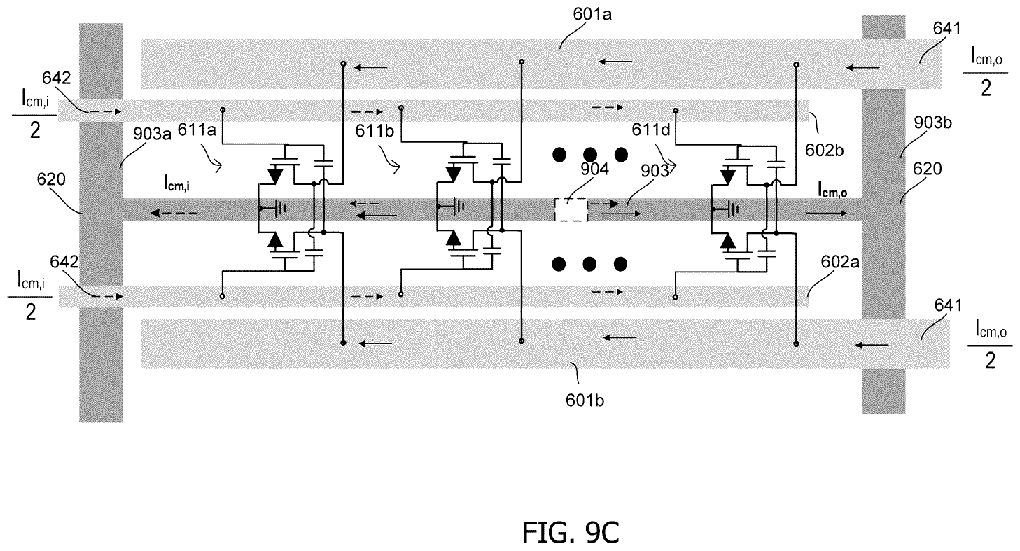

FIGS. 9A-9C show respective schematic examples of an amplifier circuitry in accordance with aspects described herein. The amplifier circuitry 900 (e.g. the amplifier circuitry 900) has been illustrated to include NMOS-based differential amplifiers but in examples, the amplifier circuitry may include PMOS-based differential amplifiers in accordance with the aspects described herein. The amplifier circuitry 900 may be a PA used in a communication circuit. Illustratively, in differential mode, the amplifier circuitry 900 may be configured to receive communication signals to be amplified from differential input connections 902a-b and provide amplified communication signals from differential output connections 901a-c. For example, the differential input connections 902a-b may be connected to a transformer to receive differential input signals. The amplifier circuitry 900 may further receive common mode input signals via differential input connections 902a-b as described above.

Various components and corresponding connections of these components of the amplifier circuitry 900 have been illustrated in FIG. 9. The amplifier circuitry may include a plurality of differential amplifier pairs 611a-d. Each differential amplifier pair 611a-d may include a pair of transistors, namely a first transistor 901 including a gate, a source, and a drain terminal, and a second transistor 902 including a gate, a source, and a drain terminal, in which the source of the first transistor 901 is coupled to the source of the second transistor 902. Furthermore, the amplifier circuitry may include a return current connection 903 (i.e. a common mode return current connection), which may be the ground connection (e.g. coupled to the ground) connected to the differential amplifier pairs 611a-d as illustrated herein for NMOS-based differential amplifier pairs. In a PMOS-based architecture, the return current connection 903 may be the supply connection (e.g. coupled to the positive supply voltage). The return current connection 903 may include a non-conductive gap 904 between the first portion of the return current connection 903a and the second portion of the return current connection 903b.

Compared to aspects described with respect to FIG. 7, directions of common mode currents have also been illustrated in FIG. 9. Arrows with dashed lines illustrate common mode currents arising from signals flowing through the differential input connections 602a-b while arrows with solid lines illustrate common mode currents arising from signals flowing through the differential output connections 601a-b. As described herein, the non-conductive gap 904 may cause the common mode return currents associated with the differential input connections 602a-b and the differential output connections 601a-b to flow in the same direction. Each common mode magnetic coupling coefficient of each differential pair amplifier 611a-d may be positive. this may result in a better common mode stability for the NDP array compared to the amplifier circuitry described in accordance with FIG. 7. In other words, the same level of common mode stability of a larger NDP array can be realized compared to the NDP array of FIG. 7, thus producing a higher output power.

In general, the spatial location of the non-conductive gap 904 or the size of the non-conductive gap 904 may vary, provided that the common mode return currents are caused to flow in the same direction illustratively by dividing the return current connection 903 into two portions electrically separated from each other via the non-conductive gap 904. The non-conductive gap is provided at the whole cross-section of the return current connection 903, such that the first portion and the second portion are electrically disconnected at two respective ends by the non-conductive gap 904.

As illustrated herein, the plurality of differential pair amplifiers may be provided on a plane extending in a row between two ends of the amplifier circuitry 900, such that each differential pair amplifier is provided next to another differential pair amplifier. A first differential pair amplifier 61 la may be located at the one end of the row (i.e. a first end). A last differential pair amplifier 611d may be located at the other end of the row (i.e. a second end). The amplifier circuitry 900 may further include one or more differential pair amplifiers 611c-d between the first differential pair amplifier 611a and the last differential pair amplifier 611d in the row. Illustratively, the input connections 602a-b may also be provided at the one end and the output connections 601a-b may be provided at the other end of the row.

The location of the non-conductive gap 904 may be anywhere on the return current connection 903 provided that the electrical disconnection is provided between the first portion and the second portion by the non-conductive gap 904 to cause the return direct currents to flow in the same direction. In other words, the non-conductive gap 904 may need to be sufficiently large to ensure that high frequency common-mode currents flow in the intended direction for positive magnetic coupling. In some examples, the non-conductive gap 904 may be provided at or close to one of the ends of the row, as it may reduce the complexity of providing the non-conductive gap in a circuit (e.g. within an integrated circuit).

FIG. 9A shows the schematic example of the amplifier circuitry, in which the non-conductive gap is provided (e.g. disposed) at the first end. The first end may be the end at which a differential input supply line is connected to the differential input connections 602a-b. Illustratively, the differential input supply line may be connected to an input transformer that provides input signals of the amplifier circuitry 900 to the differential input connections 602a-b.

FIG. 9B shows the schematic example of the amplifier circuitry, in which the non-conductive gap is provided (e.g. disposed) at the second end. The second end may be the end at which a differential output supply line is connected to the differential output connections 601a-b. Illustratively, the differential output supply line may be coupled to a matching network and/or an antenna configured to transmit output signals of the amplifier circuitry 900.

FIG. 9C shows another schematic example of the amplifier circuitry. In this illustrative example, the non-conductive gap 904 may be provided at a spatial location that is substantially in the middle of the array. Illustratively, for an amplifier circuitry including N number of differential pair amplifiers 611a-d, the non-conductive gap 904 may be provided such that there are N/2 differential pair amplifiers between the first end and the non-conductive gap 904 in an axis crossing perpendicularly the plane in which the row extends and there are N/2 further differential pair amplifiers between the non conductive gap 904 and the second end of the row in the axis crossing perpendicularly the plane in which the row extends.

Correspondingly, the electromigration limit of the return current connection (i.e. ground connection or positive supply connection depending on transistor types) may be in the system illustrated in FIG. 9 less compromised compared to cases in FIGS. 9A and 9B, as the return current connection may allow the DC current to leave from both sides of the amplifier circuitry and provide a better electromigration.

The detailed description refers to the accompanying drawings that show, by way of illustration, specific details and aspects of this disclosure in which the disclosure may be practiced. Other aspects may be utilized and structural, logical, and electrical changes may be made without departing from the scope of the disclosure. The various aspects of this disclosure are not necessarily mutually exclusive, as some aspects of this disclosure can be combined with one or more other aspects of this disclosure to form new aspects.

The word “exemplary” is used herein to mean “serving as an example, instance, or illustration”. Any aspect of the disclosure or design described herein as “exemplary” is not necessarily to be construed as preferred or advantageous over other aspects or designs.

Throughout the drawings, it should be noted that like reference numbers are used to depict the same or similar elements, features, and structures, unless otherwise noted.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in a plural form that does not expressly state “plurality” or “multiple” likewise refers to a quantity equal to or greater than one.

As used herein, “memory” is understood as a non-transitory computer-readable medium in which data or information can be stored for retrieval. References to “memory” included herein may thus be understood as referring to volatile or non-volatile memory, including random access memory (“RAM”), read-only memory (“ROM”), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

In the context of this disclosure, the term “process” may be used, for example, to indicate a method. Illustratively, any process described herein may be implemented as a method (e.g., a channel estimation process may be understood as a channel estimation method). Any process described herein may be implemented as a non-transitory computer readable medium including instructions configured, when executed, to cause one or more processors to carry out the process (e.g., to carry out the method).

“The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one clement from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, cither temporally, spatially, in ranking, or in any other manner.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in computer readable storage medium prior to its receipt by the receiving component and the receiving component may retrieve the signal from the storage medium. Further, a “value” that is “indicative of” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As utilized herein, terms “module”, “component,” “system,” “circuit,” “element,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

The term “antenna” or “antenna structure”, as used herein, may include any suitable configuration, structure and/or arrangement of one or more antenna elements, components, units, assemblies and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a single element antenna, a set of switched beam antennas, and/or the like.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “applied” to an element, the voltage, current, or signal may be conducted to the element by way of a physical connection or by way of capacitive, electro-magnetic, or inductive coupling that does not involve a physical connection. The following examples pertain to further aspects of this disclosure.

In example 1, the subject matter includes an amplifier circuitry that may include: a plurality of differential pair amplifiers connected between differential input connections and differential output connections, each differential pair amplifier of the plurality of differential pair amplifiers may include: a first transistor may include a gate, a source, and a drain; a second transistor may include a gate, a source coupled to the source of the first transistor, and a drain; and a common mode return current connection connected to the sources of the first transistors of each differential pair amplifier of the plurality of differential pair amplifiers, wherein the common mode return current connection includes an insulation layer (e.g. a non-conductive gap) between a first portion of the common mode return current connection and a second portion of the common mode return current connection.

In example 2, the subject matter of example 1, wherein the common mode return current connection is configured to conduct, for each differential pair amplifier of the plurality of differential pair amplifiers, common mode return currents associated with input and output signals of the respective differential pair amplifier.

In example 3, the subject matter of example 2, wherein the common mode return current connection is arranged to cause input common mode signals and output common mode signals of at least one differential pair amplifier of the plurality of differential pair amplifiers to flow at the same direction.

In example 4, the subject matter of example 2 or example 3, wherein the input common mode signals are associated with a first return current of the common mode return currents and the output common mode signals are associated with a second return current of the common mode return currents; wherein the common mode return current connection is arranged to cause the first return current and the second return to flow at the same direction.

In example 5, the subject matter of example 4, wherein the insulation layer causes the first return current and the second return current to flow at the same direction.

In example 6, the subject matter of example 5, wherein each differential pair amplifier of the plurality of differential pair amplifiers is associated with a respective common mode magnetic coupling measure between respective differential input connections of the differential pair amplifier and respective differential output connections of the differential pair amplifier; wherein the respective common mode magnetic coupling measures for the plurality of differential pair amplifiers are positive.

In example 7, the subject matter of example 6, wherein the insulation layer causes the respective common mode magnetic coupling measures for the plurality of differential pair amplifiers to be positive.

In example 8, the subject matter of any one of examples 1 to 7, wherein the plurality of differential pair amplifiers includes N number of differential pair amplifiers disposed on a plane extending in a row between a first end to a second end.

In example 9, the subject matter of example 8, wherein the insulation layer is disposed at the first end; wherein the differential input connections are connected to a differential input supply line at the first end.

In example 10, the subject matter of example 9, wherein the differential input supply line is connected to an input transformer.

In example 11, the subject matter of example 8, wherein the insulation layer is disposed at the second end; wherein the differential output connections are connected to a differential output supply line at the second end.

In example 12, the subject matter of example 8, wherein the insulation layer is provided, such that first N/2 number of differential pair amplifiers of the N number of differential pair amplifiers are connected to the first portion of the common mode return current connection and second N/2 number of differential pair amplifiers of the N number of differential pair amplifiers are connected to the second portion of the common mode return current connection.

In example 13, the subject matter of any one of examples 1 to 13, wherein the drains of the first transistors and drains of the second transistors are connected to the differential output connections; wherein the gates of the first transistors and the gates of the second transistors are connected to the differential input connections.

In example 14, the subject matter of any one of examples 1 to 14, wherein each of the first transistor and the second transistor of each differential amplifier pair is an NMOS; wherein the common mode return current connection is a ground connection.

In example 15, the subject matter of any one of examples 1 to 14, wherein each of the first transistor and the second transistor of each differential amplifier pair is an PMOS; wherein the common mode return current connection is a supply connection.

In example 16, the subject matter of any one of examples 1 to 15, wherein each differential pair amplifier of the plurality of differential pair amplifiers is a corresponding neutralized differential pair.

In example 17, the subject matter of any one of examples 1 to 16, wherein each differential pair amplifier of the plurality of differential pair amplifiers includes a corresponding neutralizing component configured to neutralize a parasitic capacitance.

In example 18, the subject matter of any one of examples 1 to 17, wherein the differential input connections are configured to receive a common mode input signal; wherein the differential output connections are configured to provide a common mode output signal.

In example 19, A system may include: the amplifier circuitry of any one of examples 1 to 17; a signal source coupled to the differential input connections and differential output connections; wherein the signal source is configured to generate a common mode input signal and a common mode output signal and provide them respectively to the differential input connections and the differential output connections.

In example 20, An amplifier circuitry may include: a plurality of differential pair amplifier means connected between differential input connection means and differential output connection means, each differential pair amplifier means of the plurality of differential pair amplifier means may include: a first switching means may include a gate, a source, and a drain; a second switching means may include a gate, a source coupled to the source of the first switching means, and a drain; a means to carry common mode return currents connected to the sources of the first switching means and the sources of the second switching means, wherein the means to carry common mode return currents includes an insulating means dividing the means to carry return currents into a first return current carrying portion and a second return current portion.

In example 20, the subject matter of example 19, further may include means to provide aspects described herein.

It is appreciated that implementations of methods detailed herein are exemplary in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An amplifier circuitry comprising:
a plurality of differential pair amplifiers connected to differential input connections and differential output connections, each differential pair amplifier of the plurality of differential pair amplifiers comprising:
a first transistor comprising a gate, a source, and a drain;
a second transistor comprising a gate, a source coupled to the source of the first transistor, and a drain; and
a common mode return current connection connected to the sources of the first transistors of each differential pair amplifier of the plurality of differential pair amplifiers, wherein the common mode return current connection comprises an insulation layer between a first portion of the common mode return current connection and a second portion of the common mode return current connection.

2. The amplifier circuitry of claim 1,
wherein the common mode return current connection is configured to conduct, for each differential pair amplifier of the plurality of differential pair amplifiers, common mode return currents associated with input and output signals of the respective differential pair amplifier.

3. The amplifier circuitry of claim 2,
wherein the common mode return current connection is arranged to cause input common mode signals and output common mode signals of at least one differential pair amplifier of the plurality of differential pair amplifiers to flow in the same direction.

4. The amplifier circuitry of claim 2,
wherein the input common mode signals are associated with a first return current of the common mode return currents and the output common mode signals are associated with a second return current of the common mode return currents; and
wherein the common mode return current connection is arranged to cause the first return current and the second return to flow in the same direction.

5. The amplifier circuitry of claim 4,
wherein the insulation layer causes the first return current and the second return current to flow in the same direction.

6. The amplifier circuitry of claim 5,
wherein each differential pair amplifier of the plurality of differential pair amplifiers is associated with a respective common mode magnetic coupling measure between respective differential input connections of the differential pair amplifier and respective differential output connections of the differential pair amplifier; and
wherein the respective common mode magnetic coupling measures for the plurality of differential pair amplifiers are positive.

7. The amplifier circuitry of claim 6,
wherein the insulation layer causes the respective common mode magnetic coupling measures for the plurality of differential pair amplifiers to be positive.

8. The amplifier circuitry of claim 1,
wherein the plurality of differential pair amplifiers comprises N number of differential pair amplifiers disposed on a plane extending in a row between a first end to a second end.

9. The amplifier circuitry of claim 8,
wherein the insulation layer is disposed at the first end; and
wherein the differential input connections are connected to a differential input supply line at the first end.

10. The amplifier circuitry of claim 9, wherein the differential input supply line is connected to an input transformer.

11. The amplifier circuitry of claim 8,
wherein the insulation layer is disposed at the second end; and
wherein the differential output connections are connected to a differential output supply line at the second end.

12. The amplifier circuitry of claim 8,
wherein the insulation layer is provided, such that first N/2 number of differential pair amplifiers of the N number of differential pair amplifiers are connected to the first portion of the common mode return current connection and second N/2 number of differential pair amplifiers of the N number of differential pair amplifiers are connected to the second portion of the common mode return current connection.

13. The amplifier circuitry of claim 1,
wherein the drains of the first transistors and drains of the second transistors are connected to the differential output connections; and
wherein the gates of the first transistors and the gates of the second transistors are connected to the differential input connections.

14. The amplifier circuitry of claim 1,
wherein each of the first transistor and the second transistor of each differential amplifier pair is an NMOS; and
wherein the common mode return current connection is a ground connection.

15. The amplifier circuitry of claim 1,
wherein each of the first transistor and the second transistor of each differential amplifier pair is an PMOS; and
wherein the common mode return current connection is a supply connection.

16. The amplifier circuitry of claim 1,
wherein each differential pair amplifier of the plurality of differential pair amplifiers is a corresponding neutralized differential pair.

17. The amplifier circuitry of claim 1,
wherein each differential pair amplifier of the plurality of differential pair amplifiers comprises a corresponding neutralizing component configured to neutralize a parasitic capacitance.

18. The amplifier circuitry of claim 1,
wherein the differential input connections are configured to receive a common mode input signal; and
wherein the differential output connections are configured to provide a common mode output signal.

19. A system comprising:
a plurality of differential pair amplifiers connected to differential input connections and differential output connections, each differential pair amplifier of the plurality of differential pair amplifiers comprising:
a first transistor comprising a gate, a source, and a drain;
a second transistor comprising a gate, a source coupled to the source of the first transistor, and a drain;
a common mode return current connection connected to the sources of the first transistors of each differential pair amplifier of the plurality of differential pair amplifiers, wherein the common mode return current connection comprises an insulation layer between a first portion of the common mode return current connection and a second portion of the common mode return current connection; and
a signal source coupled to the differential input connections and differential output connections; wherein the signal source is configured to generate a common mode input signal and a common mode output signal and provide them respectively to the differential input connections and the differential output connections.

20. The amplifier circuitry of claim 19,
wherein the plurality of differential pair amplifiers are configured to amplify at least one of a millimeter wave signal or a sub-Terahertz signal.
